(19) United States
(12) Patent Application Publication
(10) Pub. No.: US 2015/0236232 A1
(43) Pub. Date: Aug. 20, 2015

(54) LED PACKAGE

(71) Applicant: LITECOOL LIMITED, Sheffield, South Yorkshire (GB)

(72) Inventors: James Reeves, Nottingham (GB); Andrew Young, Sheffield (GB); Elwyn Wakefield, Chatteris (GB)

(21) Appl. No.: 14/426,525

(22) PCT Filed: Sep. 6, 2013
(86) PCT No.: PCT/GB2013/052342

§ 371 Date: Mar. 6, 2015

(30) Foreign Application Priority Data
Sep. 7, 2012 (GB) 1216025.5

(51) Int. Cl. H01L 33/64; H01L 33/54; H01L 25/075

(52) U.S. Cl. CPC H01L 33/642; H01L 25/0753; H01L 33/54; H01L 33/647

(57) ABSTRACT

According to a first aspect there is provided a light emitting diode (LED) package. The LED package comprises a heat spreader having a first side and a second side, the first side having a planar surface and the second side being asymmetrical relative to the first side. One or more LED die are mounted on a surface of the second side of the heat spreader. In particular, the surface of the second side of the heat spreader can be shaped or angled relative to the planar surface the surface of the first side.

The present invention relates to light emitting diodes and relates particularly but not exclusively to an LED package arrangement having improved cooling capabilities.

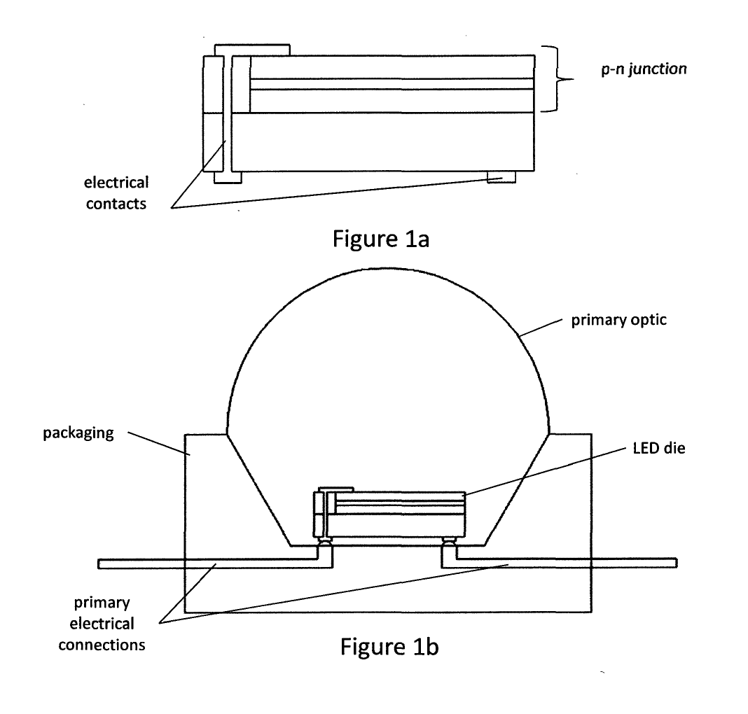

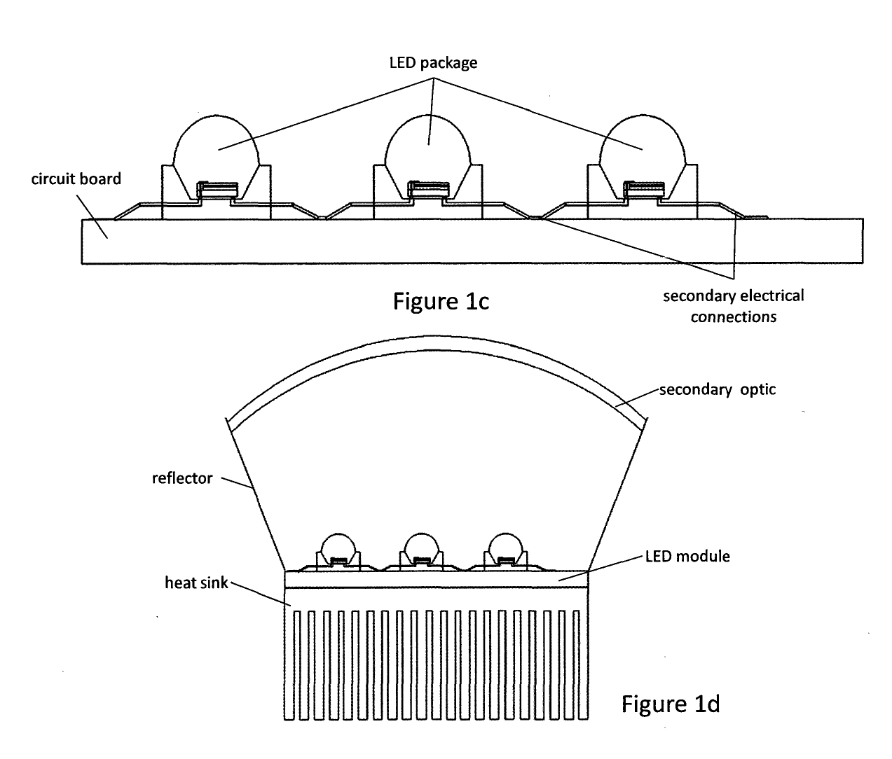

A light-emitting diode (LED) is a p-n junction semiconductor diode that emits photons when a current is applied. FIG. 1a illustrates an example of a conventional LED die comprising p and n-type semiconductor layers, a substrate and electrical contact points. Before it can be used in a practical application, a LED chip or die must be packaged. FIG. 1b illustrates an example of an LED package comprising the conventional LED die of FIG. 1a, a packaging substrate/case, primary electrical connections and commonly a primary optic in the form of a lens. One or more LED packages can then be connecting physically and electrically to a circuit board to form a LED module, such as that illustrated in FIG. 1c. One or more LED modules can then be assembled into a LED device, referred to as luminaire or lamp. FIG. 1d illustrates an example of a LED luminaire or lamp comprising a LED module, a heat sink, a reflector, and a secondary optic (secondary lens).

LED devices are a very efficient way of providing light and whilst a very large proportion of the input current is converted to light there remains a significant portion that is converted to heat and this heat must be dissipated if the LED device is to function correctly and have an acceptable lifespan. Whilst there exist a number of ways of cooling LEDs they all make use of some sort of heat dissipation device in the form of, for example, a heat sink which is attached indirectly to the LED die. Generally, the heat generated by the LED die must pass through the packaging, circuit board, and heat sink and any interfaces between these components before finally being rejected to air. This path for heat dissipation (the thermal path) can be modified for example by the introduction of one or more thermal vias passing through the circuit board to more directly connect the LED package to the heat sink. Whilst such arrangements do promote cooling they remain sub-optimal as the connection to the heat sink must be taken through the circuit board and the vias have limited thermal transmission characteristics. In addition, it is also known to replace the materials conventionally used for circuit boards which have low thermal conductivity with higher thermal conductivity materials. Again, while such arrangements do promote cooling the thermal resistance is still significant in practice. This is primarily due to their being a need to consider both the conduction (one-dimensional) thermal resistance through the thickness of the layers in the thermal path and the spreading (three-dimensional) thermal resistance from the foot print of the LED die to that of the heat sink. The spreading resistance is often neglected in the thermal design of LED packages and modules despite being the dominant contributor to their thermal resistance.

In addition, in conventional LED devices, there are typically multiple lenses, reflectors, and diffusers used in order to control the extraction and distribution of light from the individual LED die; however, each of these optical devices will induce losses (i.e. reflection and transmission losses) of around 10% thereby reducing the light output of the device.

In view of the above, there exists a demand for an improved LED package and module arrangement which reduces the problems associated with the prior art.

According to a first aspect there is provided a light emitting diode (LED) package. The LED package comprises a heat spreader having a first side and a second side, the first side having a planar surface and the second side being asymmetrical relative to the first side. One or more LED die are mounted on a surface of the second side of the heat spreader. In particular, the surface of the second side of the heat spreader can be shaped or angled relative to the planar surface the surface of the first side.

The surface of the second side of the heat spreader may be planar and at an angle relative to the surface of the first side.

Alternatively, the surface of the second side of the heat spreader may be curved. The surface of the second side of the heat spreader can then be any of convex and concave.

As a further alternative, the surface of the second side of the heat spreader can be irregular. The surface of the second side of the heat spreader can then have a plurality of planar platforms, wherein adjacent platforms are at different distances from the surface of the first side. One or more LED die can be mounted onto each platform. Each platform can be separated from an adjacent platform by a ramp portion that is at an angle relative to the platform. One or more of the plurality of platforms can be parallel with the planar surface of the first side. One or more of the plurality of platforms can be at an angle relative to the planar surface of the first side.

The surface of the second side of the heat spreader may include a concave recess and the one or more LED die can be mounted within the recess. The package can then include a plurality of LED die within the concave recess that are positioned at radially spaced positions on the concave recess and angled inwardly. The package can include a plurality of LED die within the concave recess that are positioned at radially spaced positions on the concave recess and angled inwardly towards a common point. The concave recess can comprise a plurality of substantially flat regions and wherein one or more of said one or more LED die are mounted on said one or more substantially flat regions.

The LED package can include a plurality of LED die within the concave recess and a gap between the LED die can be filled with a thermally transmitting material that extends up at least a portion of a side of one or more of said one or more LED die. The thermally transmitting material may fill the gap between each LED die and extend up at least a portion of the sides of each LED die.

The LED package may further comprise an encapsulation layer over said one or more LED die within the concave recess.

The LED package may further comprise one or more first electrical contacts, wherein the one or more first electrical contacts are electrically connected to the one or more LED die via the heat spreader. The first electrical contacts may comprise one or more projections which project beyond the surface of the second side of the heat spreader, each projection having a contact for connection to a source of electricity. The projection may extend through an electrical insulation layer to an exposed surface of the electrical insulation layer and be in electrical contact with the surface of the second side of the heat spreader.

The LED package may further comprise an electrical insulation layer having a first surface with a first electrical supply contact and a second electrical supply contact for receiving electricity from a supply thereof. The first electrical supply contact may extend through the electrical insulation layer so as to be in electrical contact with the surface of the second side of the heat spreader. The LED package may further comprise one or more wire bonds between exposed surfaces of said one or more LED die and the second electrical supply contact.

The LED package may further comprise an electrical isolation layer on the planar surface of the heat spreader.

The above and other features associated with the present invention will now be more particularly described by way of example only with reference to the accompanying drawings, in which:

FIG. 1a illustrates a cross-sectional view of an example of a conventional LED die;

FIG. 1b illustrates a cross-sectional view of an example of a conventional LED package comprising the conventional LED die of FIG. 1;

FIG. 1c illustrates a cross-sectional view of an example of a conventional LED module comprising one or more of the conventional LED packages of FIG. 1b;

FIG. 1d illustrates a cross-sectional view of an example of a conventional LED device comprising

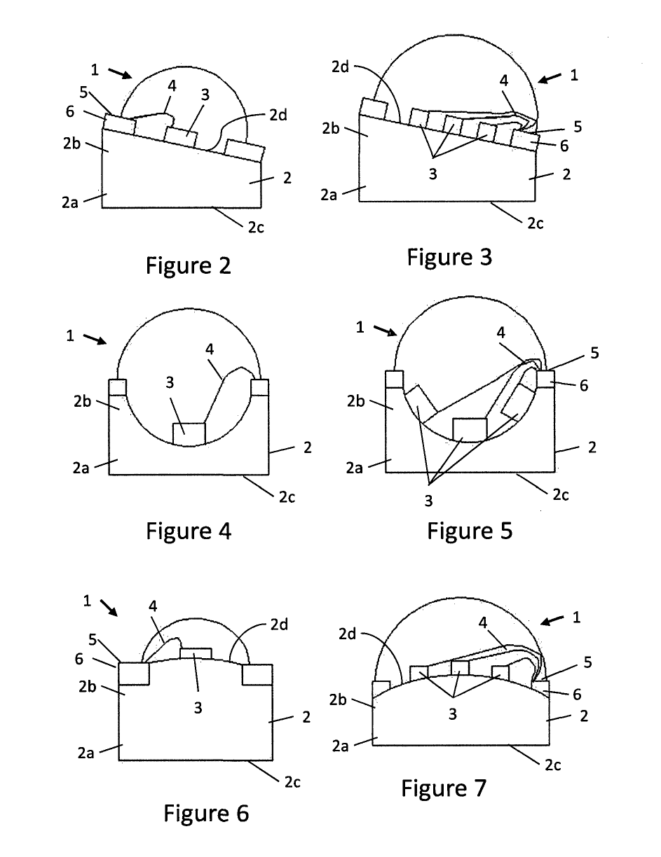

FIGS. 2 to 10 illustrates a cross-sectional view of example embodiments of an improved LED package as described herein;

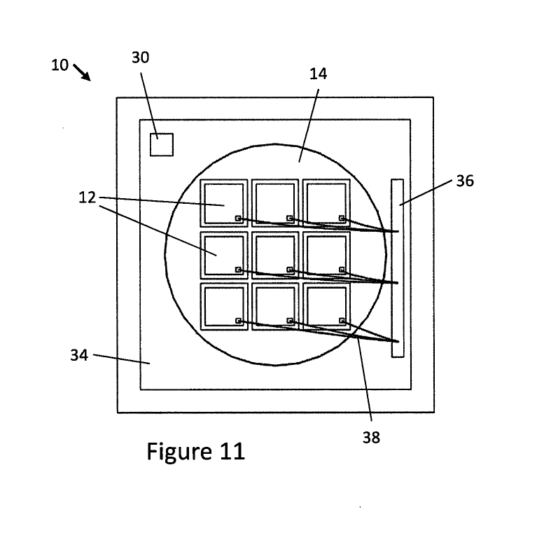

FIG. 11 illustrates a plan view of an alternative example embodiment of an LED package as described herein;

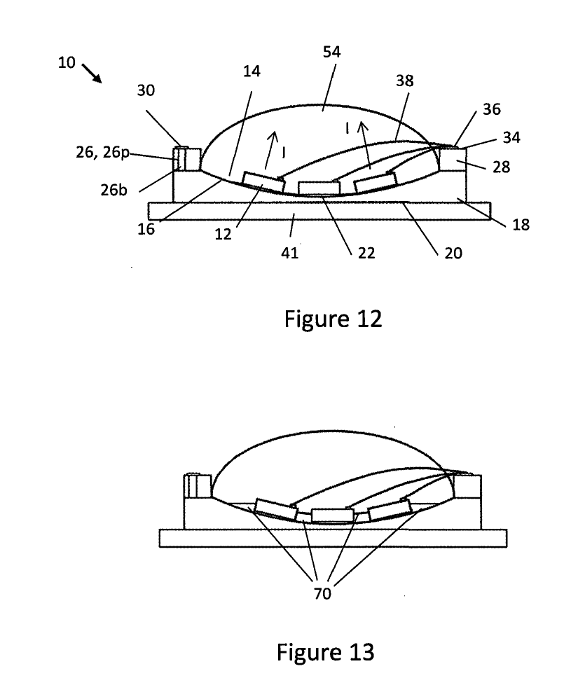

FIG. 12 illustrates a cross-sectional view of the LED package of FIG. 11; and

FIG. 13 illustrates a cross-sectional view of an alternative embodiment of the LED package of FIG. 12; and

It has been recognised by the present inventors that the number and/or severity of optical devices required to control the light output by LED die can be reduced by providing optical alignment of LED die at the LED package level. In particular, by providing an LED package in which the orientations of one or more LED die have been configured such that the LED package outputs light with a desired distribution and/or directionality, it is possible to reduce the number and/or severity of optical devices required when the LED package is used in a LED device, thereby minimising light output losses and increasing device efficiency.

To achieve this orientation of the LED die at the LED package level, the present inventors have developed a LED package in which the surface on which the LED die are mounted within the package is shaped (i.e. non-planar) or angled relative to the flat/planar reverse surface (opposite side) of the package. Shaping or angling the surface on which the LED die are mounted enables the orientation of the LED die to be configured as desired, whilst the flat/planar reverse surface allows for straightforward mounting of the package on to a circuit board or heat sink (e.g. when included within a LED module).

In addition, a further advantage of using an LED package in which the LED die are mounted onto a surface that is shaped or angled relative to the flat/planar reverse of the package is that in multi-die packages this can reduce competition in the thermal path. In particular, mounting the LED die onto a shaped or angled surface increases the separation between the LED die in the direction that is perpendicular to the base of the die (e.g. in the vertical direction), limiting the proximity of adjacent die, and thereby reducing competition for thermal gradients in the substrates and heat-spreader.

This is especially advantageous when heat-spreading resistances are dominant, as is the case in LED packaging, where the spreading-resistances are greatest local to the die, such that introducing vertical separation can greatly reduce the combined effect of multiple die on thermal resistance.

In contrast, conventional LED packages and LED modules use laminate materials such that die separation in the direction that is parallel with the base of the LED die (e.g. the horizontal direction), referred to as pitch, is the only parameter available to reduce thermal competition and interference due to their position being constrained to a planar surface.

Furthermore, by using an LED package on a heat spreader with asymmetric surfaces, this effectively increases the apparent thickness of the heat spreader thereby reducing the thermal resistance without having to increase the actual thickness of the materials used in the thermal path. Moreover, as the diffusion characteristics of a heat-source such as an LED die results in a spherical temperature field, the use of concave/convex surfaces and angled surfaces, combined with vertical and horizontal die separation, enables the die to be oriented in such a way as to minimise their thermal interference. The combination of thermal and optical advantages brought by placement of the LED die within the package and the design of the heat-spreader on which the LED dies are mounted, are complimentary to the overall luminous performance for LED packages and modules.

FIGS. 2 to 9 illustrate schematically example embodiments of an LED package 1 providing optical alignment of LED die at the LED package level. The LED package 1 comprises a heat spreader 2 having a first side 2a and a second side 2b, the first side 2a having a planar surface 2c and the second side 2b being asymmetrical relative to the first side 2a. In other words, the cross-sectional shape of the second side 2b contrasts with/differs from the cross-sectional shape of the first side 2a, wherein the term “side” refers to a part or region near the edge of the heat spreader/either of the two halves of the heat spreader. One or more LED die 3 are then mounted on a surface 2d of the second side 2b of the heat spreader 2.

The heat spreader 2 is comprised of an electrically and thermally conductive material (e.g. copper). When the LED package 1 is included in an LED module, the heat spreader 2 removes heat from the LED die and transfers the heat to a heat sink by thermal conduction, and also spreads the heat from the smaller area of the LED die to the larger heat sink. The heat spreader 2 also provides a first electrical contact for the LED die 3, as described further herein. FIGS. 2 to 9 also illustrate wire bonds 4 extending between each of the LED die 3 and a second electrical contact 5 that is separated from the heat spreader 2 by an insulation layer 6.

FIGS. 2 and 3 are cross-sectional plan views through example embodiments of a LED package 1 in which the surface 2d on which the LED die 3 is mounted is angled relative to the opposite surface 2c. In FIG. 2 the LED package 1 includes a single LED die 3, whilst in FIG. 3 the LED package 1 includes multiple LED die 3. Such an LED package provides for focusing or directional light control of the light output by the LED die. In particular, combining a number of such LED packages in an LED module or LED device can provide radial or linear dispersion or focusing of the total light output.

FIGS. 4 to 7 are cross-sectional plan views through example embodiments of a LED package 1 in which the surface 2d on which the LED die 3 are mounted is curved. In FIGS. 4 and 5 the surface 2d on which the LED die 3 are mounted is concave, whilst in FIGS. 6 and 7 the surface 2d on which the LED die 3 are mounted is convex. In FIGS. 4 and 6 the LED package 1 includes a single LED die 3, whilst in FIGS. 5 and 7 the LED package 1 includes multiple LED die 3.

An LED package in which the LED die are mounted on a concave surface of the heat spreader improves the efficiency of the heat spreading, and also provides improved protection for the LED die (i.e. as it is lower than surrounding surface). The concave surface of the LED package could also be provided with a reflective finish so as to direct more light upwards and out of the package. An LED package in which the LED die are mounted on a convex surface of the heat spreader raises die above surrounding materials to reduce light lost into these materials (i.e. shadowing).

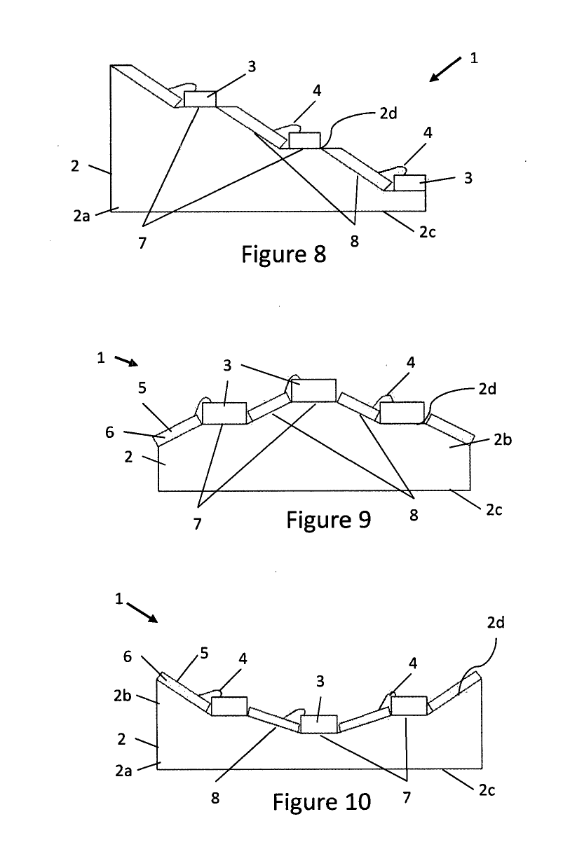

FIGS. 8 to 10 are cross-sectional plan views through example embodiments of a LED package 1 in which the surface 2d on which the LED die 3 are mounted is irregular (i.e. is uneven/multifaceted). In particular, in the example of FIGS. 8 to 10 the surface 2d on which the LED die 3 are mounted is formed with a plurality of planar platforms 7, wherein adjacent platforms are at different distances from the opposite surface 2c, and are therefore displaced vertically relative to one another. One or more LED die can then be mounted onto each platform.

An LED package in which the LED die are mounted on planar platforms that are displaced vertically relative to one another provides the possibility of more refined optical alignment of the individual die. In addition, it also provides that the surface on which the LED die are mounted can have a shape that approximates/resembles a curve, whilst allowing for better contact between the LED die and the surface for bonding. This provides better thermal, life and manufacturing properties. By way of example, shape of the surface in FIG. 9 is approximately convex whilst the shape of the surface in FIG. 10 is approximately concave.

In the embodiments illustrated in FIGS. 8 to 10, each platform 7 is separated from an adjacent platform by a ramp portion 8 that is at an angle relative to the platform. In addition, in the illustrated embodiments the platforms 7 are parallel with the planar surface of the opposite surface 2c of the heat spreader 2. However, the platforms could also be at an angle relative to the opposite surface 2c of the heat spreader 2 in order to provide specific optical characteristics.

FIGS. 11 to 13 illustrate alternative embodiments of an LED package providing optical alignment of LED die at the LED package level. The LED package 10 comprises one or more LED die 12 positioned within a curved recess 14 provided on an first (upper) surface 16 of a heat spreader 18 which also includes a second (lower) surface 20 the function of which will be described later herein. It will be appreciated that any number of die 12 may be placed within the recess. Each of the one or more LED die 12 are electrically bonded to the heat spreader by means of a die attachment layer 22 formed of, for example, solder or electrically conductive adhesive thereby to allow for the passage of electrical current between the LED die 12 and the heat spreader 18 as and when required.

Also shown in FIGS. 11 to 13 are one or more first common electrical contacts 26 to which the heat spreader 18 is connected to such as to provide a single point of electrical contact off the LED package 10. The first common contact 26 may comprise a projection 26p which projects beyond the first surface 16 of the heat spreader 18 such as to allow for a connection to be made between the contact 26 and a further electrical power supply. The first common electrical contact 26 may also project through an electrical insulation layer 28 and may include an upper contact 30 on an upper surface of the electrical insulation layer 28 for easy connection to a source of electricity. The common contact 26 may be formed as part of the electrical insulation layer 28 in which case the bottom of the connector 26b is formed such as to make electrical contact with the upper surface 16 of the heat spreader 18.

An upper surface 34 of the electrical insulation layer 28 may also be provided with one or more second common electrical contacts 36 which are each electrically connected to the LED die 12 by means of wire bonds 38 such as to allow the passage of electrical current between the die 12 and the second electrical contact(s) 36. The LED package 10 can also include an electrical isolation layer 41 on the bottom surface of the heat spreader. The upper surface of the heat spreader 18 may also be provided with an encapsulation layer 54 over one or more of the one or more die 12 which may extend over all the die 12 so as to protect them and possibly also the wire bonds from the environment and from inadvertent damage.

FIG. 12 illustrates an embodiment in which the entire bottom surface 50 is concaved and the die 12 are each positioned on the curved surface such that outer die 12a face generally inwardly in the direction of arrow I, thus providing a degree of focus to the collective light production from the multiple die 12. This arrangement may be employed in combination with the protective layer 54 acting as a lens such as to produce an even more focussed light output.

The arrangements of FIG. 13 differs from those of FIG. 12 by the addition of an amount of thermal heat transmitting material 70 such as solder or thermally transmitting adhesive at the sides of the die 12 which acts to at least partially flood the recess 14 and improve still further the degree of thermal transmission to the heat spreader. The material may extend in the gap between die such as to space fill wherever possible.

It will be appreciated that the concave recess 14 may be formed of a plurality of flat sections arranged in a generally concave shape such as to allow for individual die 12 to be mounted on the flat portions rather than a curved portion. This will allow for the enhancement of bonding and thermal transmission.

It will be appreciated that by providing the die on a shaped or angled surface it will be possible to align the die in preferred orientations and it will also be possible to improve the thermal transmission properties of the arrangement by flooding the areas around the die with thermal transmission material which enhances still further the heat transmission as the sides of the die are now also directly connected to the heat spreader.

It will be further appreciated that an LED package as described herein can be attached to a circuit board such that the surface of the heat spreader on which the LED die are mounted faces a surface of the circuit board, and leaving the opposite surface of the heat spreader exposed/uncovered. It is therefore possible to attach a heat sink to the exposed surface of the heat spreader using a thermal interface material, without the circuit board interposed between them. By providing the circuit board with one or more apertures that extend through the circuit board the LED die mounted on the adjacent surface of the heat spreader can be aligned with an aperture such that light emitted by the LED die will pass through the aperture. Prior art arrangements typically require that the LED package is mounted onto the top surface of the circuit board, such that any heat sink must then be attached to the lower surface. Complex heat transfer vias extending through the circuit board are then required which can be problematic and are costly to produce. The present arrangement allows for the LED package to be directly connected to a heat sink which may also serve as a common heat sink for a number of LED packages. This has the advantage of spreading the heat dissipation more widely and also allowing the heat dissipation capacity of one section of the heat sink to be used to support cooling of neighbouring LED packages if an immediately associated LED package is not being used.

1. A light emitting diode LED package for attachment to a heat sink transfer assembly comprising:
a heat spreader having a first side and a second side, the first side having a planar surface and the second side being asymmetrical relative to the first side; and
one or more LED die mounted on a surface of the second side of the heat spreader.

2. The light emitting diode package as claimed in claim 1, wherein the surface of the second side of the heat spreader is shaped or angled relative to the planar surface of the first side.

3. (canceled)

4. The light emitting diode package as claimed in claim 1, wherein the surface of the second side of the heat spreader is curved.

5. The light emitting diode package as claimed in claim 4, wherein the surface of the second side of the heat spreader is any of convex and concave.

6. (canceled)

7. The light emitting diode package as claimed in claim 1, wherein the surface of the second side of the heat spreader is irregular, and wherein the surface of the second side of the heat spreader has a plurality of planar platforms, wherein adjacent platforms are at different distances from the surface of the first side.

8. The light emitting diode package as claimed in claim 7, wherein one or more LED die are mounted onto each platform.

9. (canceled)

10. (canceled)

11. The light emitting diode package as claimed in claim 7, wherein one or more of the plurality of platforms are at an angle relative to the planar surface of the first side.

12. The light emitting diode package as claimed in claim 1, wherein the surface of the second side of the heat spreader includes a concave recess and the one or more LED die are mounted within the recess.

13. The light emitting diode package as claimed in claim 12, wherein the package includes a plurality of LED die within the concave recess that are positioned at radially spaced positions on the concave recess and angled inwardly.

14. The light emitting diode package as claimed in claim 12, wherein the package includes a plurality of LED die within the concave recess that are positioned at radially spaced positions on the concave recess and angled inwardly towards a common point.

15. The light emitting diode package as claimed in claim 12, wherein the concave recess comprises a plurality of substantially flat regions and wherein one or more of said one or more LED die are mounted on said one or more substantially flat regions.

16. The light emitting diode package as claimed in claim 12, and wherein the package includes a plurality of LED die within the concave recess and a gap between the LED die is filled with a thermally transmitting material extending up at least a portion of a side of one or more of said one or more LED die.

17. The light emitting diode package as claimed in claim 12, wherein the package includes a plurality of LED die within the concave recess and a gap between the LED die is filled with a thermally transmitting material extending up at least a portion of a side of one or more of said one or more LED die, and wherein said thermally transmitting material fills the gap between each LED die and extends up at least a portion of the sides of each LED die.

18. The light emitting diode package as claimed in claim 12, further comprising an encapsulation layer over said one or more LED die within the concave recess.

19. The light emitting diode package as clamed in claim 1, and further comprising one or more first electrical contacts, wherein the one or more first electrical contacts are electrically connected to the one or more LED die via the heat spreader.

20. The light emitting diode package as claimed in claim 19, wherein the first electrical contacts comprise one or more projections which project beyond the surface of the second side of the heat spreader, each projection having a contact for connection to a source of electricity.

21. The light emitting diode package as claimed in claim 19, wherein the first electrical contacts comprise one or more projections which project beyond the surface of the second side of the heat spreader, each projection having a contact for connection to a source of electricity, and wherein said projection extends through an electrical insulation layer to an exposed surface of the electrical insulation layer and is in electrical contact with the surface of the second side of the heat spreader.

22. The light emitting diode package as claimed in claim 1, and further comprising an electrical insulation layer having a first surface with a first electrical supply contact and a second electrical supply contact for receiving electricity from a supply thereof.

23. The light emitting diode package as claimed in claim 22, and including one or more wire bonds between exposed surfaces of said one or more LED die and the second electrical supply contact.

24. The light emitting diode arrangement as claimed in claim 1, and including an electrical isolation layer on the planar surface of the heat spreader.
